(19) United States
(12) Patent Application Publication
(10) Pub. No.: US 2025/0113720 A1
(43) Pub. Date: Apr. 3, 2025

(54) DISPLAY PANEL, MANUFACTURE METHOD THEREOF, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Lin ZHANG, Beijing (CN); Yaqiu LI, Beijing (CN)

(21) Appl. No.: 18/576,347

(22) PCT Filed: Apr. 28, 2023
(86) PCT No.: PCT/CN2023/091688

§ 371 Date: Jan. 3, 2024

(51) Int. Cl. H10K 59/80; H10K 59/35; H10K 102/00

(52) U.S. Cl. CPC H10K 59/8791; H10K 59/35; H10K 2102/311

(57) ABSTRACT

A display panel is provided, including a non-bending area and at least one bending area on a side of the non-bending area. The display panel includes a substrate, a light emitting layer and a color shift improvement layer. The light emitting layer is on the substrate, includes a plurality of light-emitting units. Each light-emitting unit includes a plurality of light-emitting subunits. The light-emitting subunits can emit first color light, second color light and third color light; and the color shift improvement layer is on the side of the light emitting layer facing away from the substrate and on at least one bending area; difference values in the light emission ratios of the first color light, the second color light and the third color light in the frontal viewing direction range from 0-8%, and the frontal view direction is perpendicular to at least part of the surface of the non-bending area.

### TECHNICAL FIELD

The present disclosure relates to display technology, and in particular, to a display panel, a manufacture method thereof, and a display device.

### BACKGROUND

Flexible display panels (such as flexible OLED (Organic Light-Emitting Diode) panels) receives more and more attention and applications due to their advantages of bendability, easy portability, and wide range of applications. After display areas of the flexible display panel are bent, when viewing the display panel vertically, the color shift will appear in the curved part, and the color shift will become more serious as the bending angle of the bending area increases, affecting viewing experience of the viewer.

### SUMMARY

A first aspect of embodiments of the present disclosure provides a display panel, including a non-bending area and at least one bending area on at least one side of the non-bending area, where the display panel includes:
a substrate;
a light emitting layer, provided on the substrate, where the light emitting layer includes a plurality of light-emitting units, each of the plurality of light-emitting units includes a plurality of light-emitting subunits, the plurality of light-emitting subunits are able to emit a first color light, a second color light, and a third color light; and
a color shift improvement layer, provided on a side of the light emitting layer facing away from the substrate, and on the at least one bending area;
difference values between light emission ratios of the first color light, the second color light, and the third color light in a frontal viewing direction range from 0-8%, where the frontal viewing direction is perpendicular to at least a part of a surface of the non-bending area.

In some embodiments, the difference values between the light emission ratios of the first color light, the second color light, and the third color light in the frontal viewing direction range from 0-5%.

In some embodiments, in the bending area, an initial light emission ratio of the first color light in the frontal viewing direction is greater than an initial light emission ratio of the second color light in the frontal viewing direction, the initial light emission ratio of the second color light in the frontal viewing direction is greater than an initial light emission ratio of the third color light in the frontal viewing direction;
the color shift improvement layer is provided with a first color resist material for reducing a first color light transmittance.

In some embodiments, the color shift improvement layer simultaneously reduces the light emission ratios of the first color light and the second color light in the frontal viewing direction, such that the difference values between the light emission ratios of the first color light, the second color light, and the third color light in the frontal viewing direction are reduced to a preset difference value; the color shift improvement layer is provided with a first color resistance material for reducing the first color light transmittance and a second color resist material for reducing the second color light transmittance.

In some embodiments, in the bending area, a first color light transmittance in the frontal viewing direction of the color shift improvement layer is a first color shift transmittance, a second color light transmittance in the frontal viewing direction of the color shift improvement layer is a second color shift transmittance, and the first color shift transmittance is less than or equal to the second color shift transmittance.

In some embodiments, the color shift improvement layer is completely transparent to the third color light; and/or,
among the first color light, the second color light and the third color light, one is red light, one is green light, and one is blue light.

In some embodiments, the bending area is able to be divided into one or more bending subareas, a number of the bending subareas is divided based on a range of a frontal viewing angle of the bending area of the display panel; where, different bending subareas have a different transmittance for at least one color light, a bending angle of each bending subarea is a preset angle, the preset angle is greater than or equal to 5° and less than or equal to 15°.

In some embodiments, the display panel includes an encapsulation layer provided on the side of the light emitting layer facing away from the substrate; where, the color shift improvement layer is provided on a side of the encapsulation layer facing away from light emitting layer, or the color shift improvement layer is provided between the encapsulation layer and the light emitting layer.

A second aspect of embodiments of the present disclosure provides a method of manufacturing a display panel, for manufacturing the display panel as described above, the method includes:
determining corresponding relationships between light emission ratios respectively for a first color light, a second color light, and a third color light at frontal viewing angles of the display panel and the frontal viewing angles;
determining a range of the frontal viewing angles of the display panel to determine a bending area of the display panel;
determining a color shift improvement layer, based on the range of the frontal viewing angle of the bending area of the display panel, and the corresponding relationships between the light emission ratios respectively for the first color light, the second color light, and the third color light at the frontal viewing angle of the display panel and the frontal viewing angle; and
manufacturing the display panel based on the color shift improvement layer;
where difference values between the light emission ratios of the first color light, the second color light, and the third color light in the frontal viewing direction range from 0-8%.

In some embodiments, in the bending area, an initial light emission ratio of the first color light in the frontal viewing direction is greater than an initial light emission ratio of the second color light in the frontal viewing direction, and the initial light emission ratio of the second color light in the frontal viewing direction is greater than an initial light emission ratio of the third color light in the frontal viewing direction; the method of manufacturing the display panel based on the color shift improvement layer includes:
providing a first color resist material for reducing the first color light transmittance in the color shift improvement layer to reduce the light emission ratio of the first color light in the frontal viewing direction.

In some embodiments, in the bending area, an initial light emission ratio of the first color light in the frontal viewing direction is greater than an initial light emission ratio of the second color light in the frontal viewing direction; and the initial light emission ratio of the second color light in the frontal viewing direction is greater than an initial light emission ratio of the third color light in the frontal viewing direction.

Manufacturing the display panel based on the color shift improvement layer includes:
providing a first color resistance material for reducing the first color light transmittance and a second color resist material for reducing the second color light transmittance in the color shift improvement layer;
where, in the bending area, the first color light transmittance in the frontal viewing direction of the color shift improvement layer is a first color shift transmittance, the second color light transmittance in the frontal viewing direction of the color shift improvement layer is a second color shift transmittance, and the first color shift transmittance is less than or equal to the second color shift transmittance.

In some embodiments, the method further includes:
dividing the bending area into one or more bending subareas based on bending angles of the bending area of the display panel, where different bending subareas have a different transmittance for at least one color light; a bending angle of each bending subarea is a preset angle, where the preset angle is greater than or equal to 5° and less than or equal to 15°.

A third aspect of embodiments of the present disclosure provides a display device, the display device includes the display panel as described above.

The display panel and the display device provided in the present application, by providing a color shift improvement layer in at least one bending area in the display panel, make the difference values between the light emission ratios of the first color light, the second color light, and the third color light in the frontal viewing direction range from 0-8%, which is beneficial to improve the color shift phenomenon brought about by the bending of the display panel, thereby improving the visual experience of the user watching the display panel.

It should be understood that the above general descriptions and the below detailed descriptions are merely examples and explanation, and are not intended to limit the present disclosure.

### BRIEF DESCRIPTION OF DRAWINGS

The accompanying drawings herein, which are incorporated into the specification and constitute a part of this specification, illustrate embodiments consistent with the present disclosure, and together with the specification, serve to explain the principles of the present disclosure.

FIG. 1 is a frontal view of a display device according to embodiments of the present disclosure;

FIG. 2 is a sectional view of a display panel in a flat state according to embodiments of the present disclosure;

FIG. 3 is a partial sectional view of a display panel in a flat state according to embodiments of the present disclosure;

FIG. 4 is a schematic diagram of a display panel in a bent state according to embodiments of the present disclosure;

FIG. 5 is a schematic diagram of area division of a display panel according to embodiments of the present disclosure;

FIG. 6 shows curves of corresponding relationships between the light emission ratios at frontal viewing angles and the frontal viewing angles according to embodiments of the present disclosure;

FIG. 7 is a comparison table between light emission ratios at a part of frontal viewing angles and bending angles for a display panel according to embodiments of the present disclosure;

FIG. 8 is a comparison table between light emission ratios at a part of frontal viewing angles and bending angles for a display panel before improvement in the related art;

FIG. 9 is a comparison table between light emission ratios at a part of frontal viewing angles of the color shift improvement layer and bending angles according to embodiments of the present disclosure;

FIG. 10 is a comparison table between light emission ratios at a part of frontal viewing angles and bending angles for a display panel after improvement according to embodiments of the present disclosure;

FIG. 11 is a flow chart of a method of manufacturing a display panel according to embodiments of the present disclosure.

### DETAILED DESCRIPTION

Embodiments will be described in detail here, examples of which are illustrated in the accompanying drawings. When the following description relates to the accompanying drawings, unless specified otherwise, the same numerals in different drawings represent the same or similar elements. Implementations described in the following examples do not represent all implementations consistent with the present disclosure. Rather, they are merely device examples consistent with some aspects of the present disclosure as detailed in the appended claims.

The terms used in this application are merely for the purpose of describing specific embodiments, and are not intended to limit this application. Unless otherwise stated, the technical terms or scientific terms used in the present disclosure should have general meanings that are understandable by persons of ordinary skills in the art. The terms “a” or “an” and the like used in the specification and the claims of the present disclosure do not mean a quantity limit, but mean that there is at least one. The term “a plurality” indicates two or more, unless specifically defined otherwise. The terms such as “comprise,” “include”, or any variant thereof mean that an element or article preceded by “comprise” or “include” encompasses elements or articles and their equivalents listed after “comprise” or “include”, do not exclude the existence of other elements or articles. “Connected to” or “connected with” and similar terms are not limited to physical or mechanical connections, and can include electrical connections, whether direct or indirect. Unless otherwise stated, the terms such as “lower,” and/or “upper” are for ease of description only and are not limited to a position or a spatial orientation. The singular forms such as “a,” “said,” and “the” used in the present disclosure and the appended claims are also intended to include multiple, unless the context clearly indicates otherwise. It should also be understood that the term “and/or” used herein includes any and all possible combinations of one or more of the associated listed items.

The present disclosure provides a display panel and a display device. The display panel includes a substrate, a light emitting layer and a color shift improvement layer. The light emitting layer is provided on the substrate, including a plurality of light-emitting units, each of the plurality of light-emitting units includes a plurality of light-emitting subunits, the plurality of light-emitting subunits are able to emit a first color light, a second color light, and a third color light. The color shift improvement layer is provided on a side of the light emitting layer facing away from the substrate, and on at least one bending area; in the display panel, difference values between the light emission ratios of the first color light, the second color light, and the third color light in the frontal viewing direction are reduced to a preset difference value; where the frontal viewing direction is perpendicular to at least a part of the surface of the non-bending area. The above-mentioned display panel, by providing a color shift improvement layer in the at least one bending area in the display panel, makes the difference values between the light emission ratios of the first color light, the second color light, and the third color light in the frontal viewing direction range from 0-8%, which is beneficial to improve the color shift phenomenon brought about by the bending of the display panel, thereby improving the visual experience of the user watching the display panel.

The display panel mentioned in the present disclosure may be a flexible OLED panel. The display panel may be applied to mobile phones, tablet computers, televisions, laptops, and other products or components with display functions, and as a display panel of mobile phones, tablet computers, televisions, laptops, and other products or components with display functions.

The display panel and display device provided in the present application are described in detail below referring to FIG. 2 to FIG. 10.

The present disclosure provides a display device 100. The display device 100 may include display panel 2 or a similar display panel. The display device 100 further includes device body 1 having a housing. The display panel 2 or the similar display panel may be specifically assembled on device body 1.

The display device here may be a mobile phone, a tablet computer, a television, a laptop, and other product or component with the display function.

The display panel 2 mentioned here may be a flexible organic light emitting diode (OLED) panel.

The display panel 2 includes a non-bending area S1 and at least one bending area S2 on at least one side of the non-bending area S1, the display panel 2 includes substrate 10, light emitting layer 30, and color shift improvement layer 50. The light emitting layer 30 is provided on substrate 10, including a plurality of light-emitting units, each light-emitting unit includes a plurality of light-emitting subunits, the plurality of light-emitting subunits are able to emit a first color light, a second color light, and a third color light.

The color shift improvement layer 50 is provided on a side of the light emitting layer 30 facing away from the substrate 10, and on the at least one bending area S2;
In the display panel 2, the difference values between the light emission ratios of the first color light, the second color light, and the third color light in the frontal viewing direction are a preset difference value; where the frontal viewing direction is perpendicular to at least a part of a surface of the non-bending area S1.

In some embodiments, a range of the preset difference values is 0-8%.

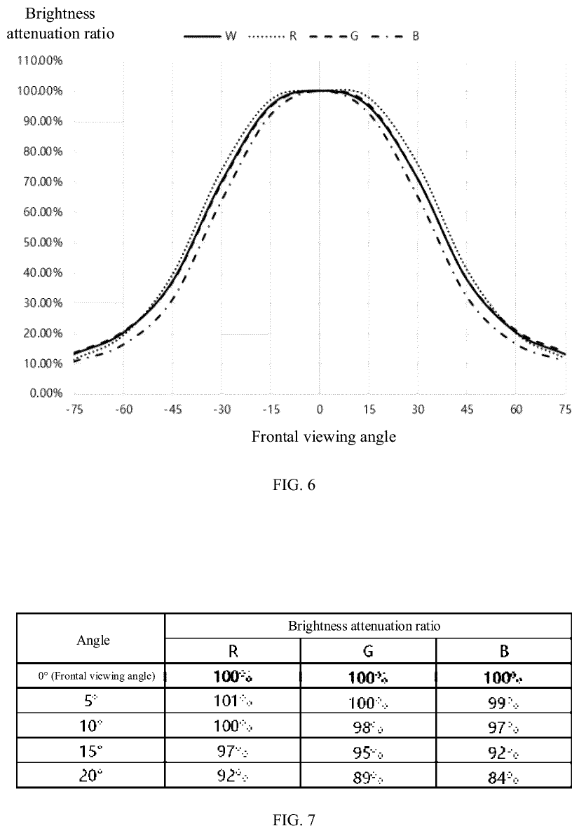

Among the first color light, the second color light and the third color light mentioned here, one is red light, one is green light, and one is blue light. As shown in FIG. 6 and FIG. 7, taking the first color light being red light, the second color light being green light, and the third color light being blue light as an example for explanation.

It is understandable that, the light-emitting subunit may be a subpixel unit that emits monochromatic light, such as an RGB subpixel unit. Correspondingly, in some embodiments, each light-emitting unit may include three light-emitting subunits, which are respectively used for emitting red light, green light, and blue light.

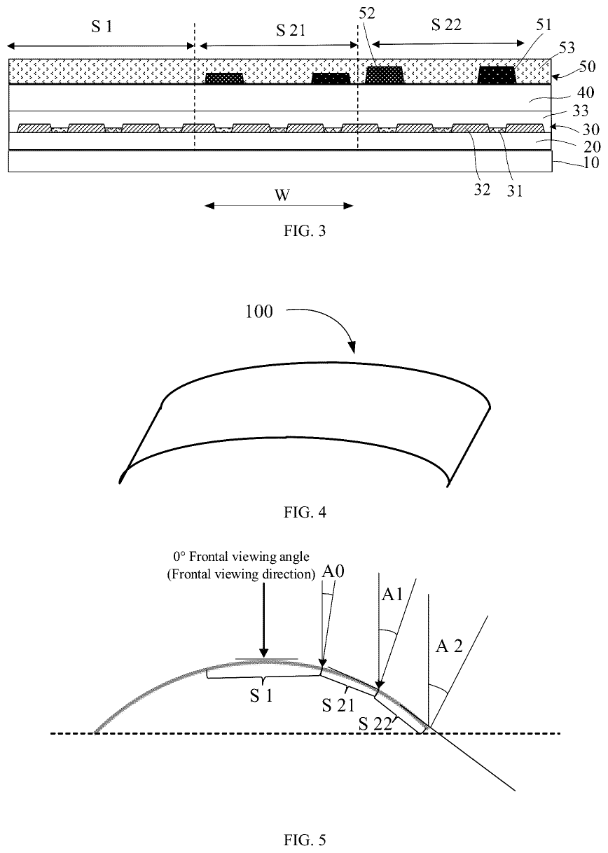

As shown in FIG. 3, light emitting layer 30 may include light-emitting subpixels 31, a pixel-defining layer 32 and a planarization layer 33. Pixel-defining layer 32 defines a plurality of pixel openings. Each of the light-emitting subpixels 31 may be provided in a pixel opening defined by the pixel-defining layer 32.

In some embodiments, the display panel 2 includes an encapsulation layer 40 provided on a side of the light emitting layer 30 facing away from the substrate 10. The color shift improvement layer 50 is provided on a side of the encapsulation layer 40 facing away from the light emitting layer 30.

Non-bending area S1 may be an area where the entire area is flat, a part of the area is flat, or the entire area is slightly bent. For example, as shown in FIG. 5, the entire display panel is slightly bent, in which the degree of bending or the bending angle of the non-bending area S1 (hereinafter referred to as the frontal viewing angle) can be determined based on the specific situation. Correspondingly, a part of a contiguous area with a frontal viewing angle less than or equal to A0 degrees may be considered as a non-bending area. The specific degrees for the frontal viewing angle A0 may be determined based on the specific situation. For example, in some embodiments, the degrees for the frontal viewing angle A0 are 3°. Correspondingly, the area less than or equal to 3° may be considered as a non-bending area.

The frontal viewing direction is perpendicular to the direction of the surface of the non-bending area. It is understandable that, for a non-bending area having a flat area, the frontal viewing direction is perpendicular to the direction of the flat area; for a non-bending area without a flat area, the frontal viewing direction may be understood as perpendicular to the direction of the outer tangent line at a relatively flat surface of the non-bending area, such as the direction of the 0° frontal viewing angle shown in FIG. 5.

The frontal viewing angle at a certain position in the display panel may be understood as the angle between the perpendicular line of the tangent at the position in the display panel and the frontal viewing direction. It is understandable that, for a display panel having a flat area, the frontal viewing angle of the flat area is 0°. For a bent area in the display panel, the frontal viewing angle varies with the bending angles. That is, in a bent area, the frontal viewing angle at a certain position is, the angle between the perpendicular line of the tangent at the position in the display panel and the frontal viewing direction.

In some embodiments, the preset difference value ranges form 0-5%.

The inventor found through research that: the smaller the preset difference value is, the better the color shift improvement effect is. When the preset difference value is 0 or close to 0, which can make the light emission ratios of the first color light, the second color light, and the third color light in the frontal viewing direction the same or basically the same, such that the overall viewing effect for users is basically not affected by the bending of the display panel.

In some embodiments, in the bending area S2, the initial light emission ratio of the first color light in the frontal viewing direction is greater than the initial light emission ratio of the second color light in the frontal viewing direction; the initial light emission ratio of the second color light in the frontal viewing direction is greater than the initial light emission ratio of the third color light in the frontal viewing direction. The color shift improvement layer 50 may reduce the light emission ratio of the first color light in the frontal viewing direction or simultaneously reduce the light emission ratios of the first color light and the second color light in the frontal viewing direction, such that the difference value between the light emission ratios of the first color light, the second color light, and the third color light in the frontal viewing direction are reduced to a preset difference value.

The initial light emission ratio can be understood as the light emission ratio of each color light in the same display panel without providing the color shift improvement layer. That is, the initial light emission ratio of each color light is, when the display panel is not provided with a color shift improvement layer, and the other structures are the same as the display panel 2 of the present disclosure, the light emission ratio of each color light. It can also be referred to as the light emission ratio before improvement.

As shown in FIG. 3, in some embodiments, the color shift improvement layer 50 simultaneously reduces the light emission ratios of the first color light and the second color light in the frontal viewing direction, such that the difference values between the light emission ratios of the first color light, the second color light, and the third color light in the frontal viewing direction are reduced to a preset difference value; the color shift improvement layer 50 is provided with a first color resistance material 51 for reducing the first color light transmittance, and a second color resist material 52 for reducing the second color light transmittance.

It is understandable that, in the present disclosure, the light emission ratio is the transmittance. Correspondingly, the light emission ratio in the frontal viewing direction is the transmittance in the frontal viewing direction.

In some embodiments, in the bending area S2, the first color light transmittance in the frontal viewing direction of the color shift improvement layer 50 is the first color shift transmittance, the second color light transmittance in the frontal viewing direction of the color shift improvement layer 50 is the second color shift transmittance, and the first color shift transmittance is less than or equal to the second color shift transmittance.

It should be noted that, the color shift improvement layer 50 has a planarization layer 53. The first color resistance material 51 and the second color resistance material 52 may be a bulk structure provided in the planarization layer 53, or a microparticle structure dispersed in the planarization layer 53. In some other embodiments, the first color resistance material 51 and the second color resistance material 52 may also form a film structure below the planarization layer 53.

In some other embodiments, the color shift improvement layer 50 reduces the light emission ratio of the first color light in the frontal viewing direction, such that the difference values between the light emission ratios of the first color light, the second color light, and the third color light in the frontal viewing direction are reduced to a preset difference value; the color shift improvement layer 50 is provided with a first color resistance material 51 for reducing the first color light transmittance.

The inventor found through research that: in the bending subareas with different degrees of bending, the larger the bending angle of the bending subareas is, the corresponding color resistance material needs to have a greater blocking effect on the corresponding color light, that is, the lower the transmittance of the corresponding color light is, the better the color shift improvement effect is.

In some embodiments, the color shift improvement layer 50 is completely transparent to the third color light, i.e., the third color light transmittance in the color shift improvement layer 50 is 100%.

In some other embodiments, the color shift improvement layer 50 may also not be completely transparent to the third color light, but have a relative higher transmittance, such as 98%, 99%, or even higher.

In some embodiments, the bending area S2 can be divided into one or more bending subareas, the number of the bending subareas is divided based on a range of a frontal viewing angle for the bending area S2 of the display panel 2; where, different bending subareas have a different transmittance for at least one color light, the bending angle of each bending subarea is a preset angle, the preset angle is greater than or equal to 5° and less than or equal to 15°.

For example, the preset angle may be selected as 10°, the specific selection of the preset angle may be set based on the specific situation of the display panel.

It is understandable that, since the bending angles of different bending subareas are different, the degrees of color shift are also different. Correspondingly, the display panel (that is, the color shift improvement layer) can be set such that, different bending subareas have different transmittances for the same color light, or have different transmittances for two color lights at the same time, to respectively improve the color shift effect.

It should be noted that, the preset angles of different bending subareas in the same display panel may be the same, or may be different.

In addition, the display panel 2 further includes a driver circuit layer 20 provided between the light emitting layer 30 and the substrate.

Based on the above description, as shown in FIG. 2, FIG. 3, FIG. 5 and FIG. 8 to FIG. 10, in some embodiments, the maximum bending angle of the display panel is 20°, that is, the maximum frontal viewing angle is 20°. Correspondingly, the display panel includes a non-bending area S1, and a bending area S2. The bending area S2 is divided into two bending subareas S21 and S22. The bending subarea S21 is between the bending area S22 and the non-bending area S1. Aland A2, the respective bending angles (frontal viewing angles) of the two bending subareas S21 and S22, are 10° and 20° respectively.

The display panel may be set such that the transmittances of the red, green, and blue light of the non-bending area are all 100%.

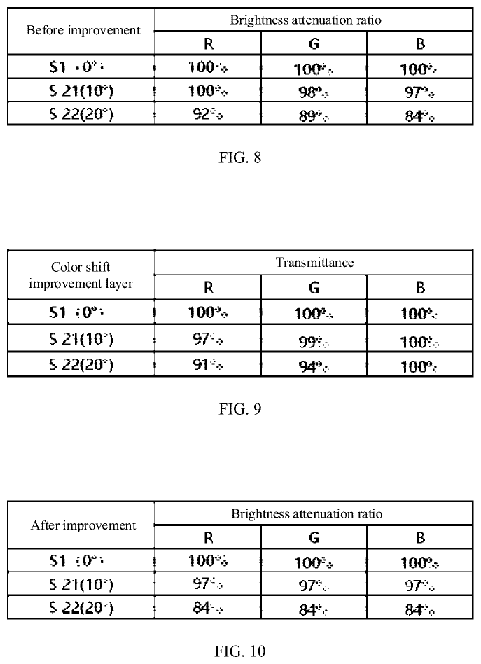

As shown in FIG. 8, before the color shift improvement layer is provided, in the bending subarea S21 of the display panel, when the frontal viewing angle is 10°, the transmittances of blue light, green light, and red light in the frontal viewing direction are 97%, 98%, and 100% respectively, that is, the initial light emission ratios of blue light, green light, and red light in the frontal viewing direction are 97%, 98%, and 100% respectively, it can be seen that the initial light emission ratio of the red light in the frontal viewing direction is greater than the initial light emission ratio of the green light in the frontal viewing direction, the initial light emission ratio of the green light in the frontal viewing direction is greater than the initial light emission ratio of the blue light in the frontal viewing direction. In the bending subarea S22, when the frontal viewing angle is 20°, the transmittances (i.e., the initial light emission ratio) of the blue light, the green light, and the red light in the frontal viewing direction are 84%, 89%, and 92% respectively.

It can be seen that, as the bending degree of the display panel increases, that is, the frontal viewing angle increases, the brightness attenuation ratio (i.e., the transmittance attenuation ratio) of the blue light decreases the fastest, followed by the green light, and the red light decreases the slowest. The color shift improvement layer improves the transmittances of red light and green light, such that the transmittances of the red light and green light in the bending subareas S21 and S22 are consistent with the corresponding transmittance of the blue light.

For example, as shown in FIG. 9, the color shift improvement layer 50 is set as that, in the bending subarea S21, when the frontal viewing angle is 10°, the transmittances of the blue light, the green light, and the red light in the frontal viewing direction are 100%, 99%, and 97% respectively; and in the bending subarea S22, when the frontal viewing angle is 20°, the transmittances of the blue light, the green light, and the red light in the frontal viewing direction are 91%, 94%, and 100% respectively.

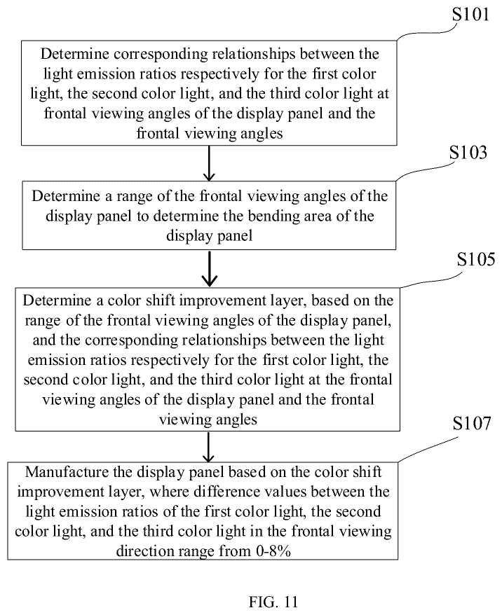

As shown in FIG. 10, after the color shift improvement layer 50 is provided, in the bending subarea S21, when the frontal viewing angle is 10°, the transmittances of the blue light, the green light, and the red light in the frontal viewing direction are 97%, 97%, and 97% respectively; and in the bending subarea S22, when the frontal viewing angle is 20°, the transmittances of the blue light, the green light, and the red light in the frontal viewing direction are 84%, 84%, and 84% respectively.

It can be seen that, through the method of the present disclosure, the color shift phenomenon of the display panel that exists due to bending can be effectively improved, such that the bending area has the same transmittance for the red, green, and blue light. Moreover, when the bending degree of the display panel is relatively large (that is, the frontal viewing angle is relatively large), dividing the bending area into different bending subareas and improving the color shift for the different bending subareas separately can achieve a better improvement effect.

It should be noted that, in some other embodiments, the color shift improvement layer 50 may also be provided between the encapsulation layer 40 and the light emitting layer 30.

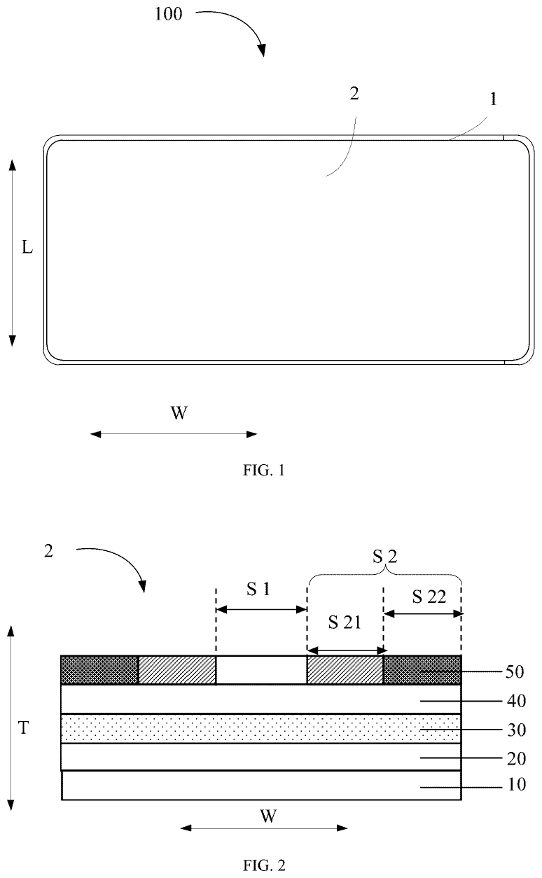

As shown in FIG. 11, and refer to FIG. 1 to FIG. 10, when necessary, the present disclosure provides a method of manufacturing a display panel 2, which can be used to manufacture the display panel 2 as described above, the method of manufacturing the display panel 2 includes the following steps S101-S107.

At step S101, the corresponding relationships between the light emission ratios respectively for the first color light, the second color light, and the third color light at frontal viewing angles of the display panel and the frontal viewing angles are determined.

At step S103, a range of the frontal viewing angles of the display panel 2 is determined to determine the bending area of the display panel.

At step S105, a color shift improvement layer is determined, based on the range of the frontal viewing angles of the display panel, and the corresponding relationships between the light emission ratios respectively for the first color light, the second color light, and the third color light at frontal viewing angles of the display panel and the frontal viewing angles.

At step S107, the display panel is manufactured based on the color shift improvement layer.

The difference values between the light emission ratios of the first color light, the second color light, and the third color light in the frontal viewing direction range from 0-8%.

In some embodiments, the preset difference value ranges from 0-5%.

The inventor found through research that: the smaller the preset difference value is, the better the color shift improvement effect is. Setting the preset difference value as 0 or close to 0 may make the light emission ratios of the first color light, the second color light, and the third color light in the frontal viewing direction the same or basically the same, such that the overall viewing effect for users is basically not affected by the bending of the display panel.

At step S101, based on the material, thickness, and other specific conditions of the display panel 2, the corresponding relationships between the light emission ratios respectively for the first color light, the second color light, and the third color light at frontal viewing angles of the display panel 2 and the frontal viewing angles are determined by calculation, testing and the like.

As shown in FIG. 6 and FIG. 7, still taking the first color light being red light, the second color light being green light, and the third color light being blue light as an example for explanation.

In some embodiments, the corresponding relationship curves between the light emission ratios respectively for the red light, the blue light, and green light at frontal viewing angles of the display panel 2 and the frontal viewing angles can be determined through step S101, as shown in FIG. 6. R represents the red light, G represents the green light, B represents the blue light, and W represents a mixture of R, G, and B.

At step S103, based on the specific product requirements of the display panel, by means of measurement, calculation, etc., the ranges of the frontal viewing angles of the display panel 2 can be determined, to determine the bending area S2 of the display panel 2.

At step S105, the color shift improvement layer 50 is determined, based on a range of the frontal viewing angles of the display panel, and the corresponding relationships between the light emission ratios respectively for the first color light, the second color light, and the third color light at frontal viewing angles of the display panel and the frontal viewing angles. Step S105 can be achieved by following steps S1051 to S1053.

At step S1051, firstly, it is necessary to determine the light emission ratio(s) of which color light or which two color lights needs to be adjusted, based on the range of the frontal viewing angle of the bending area and the corresponding relationships between the light emission ratios respectively for the first color light, the second color light, and the third color light at frontal viewing angles of the display panel and the frontal viewing angles.

Then, at step S1052, based on the brightness attenuation ratios of the specific three color lights at different frontal viewing angles, the frontal viewing angle corresponding to the bending area is determined, and based on the frontal viewing angle, brightness attenuation ratio values of respective color lights at the frontal viewing angle corresponding to the bending area are determined, for example, respective attenuation ratio values are shown in the table of FIG. 8.

Moreover, at step S1053, based on the brightness attenuation ratio values of respective color lights at the frontal viewing angle corresponding to the bending area, the transmittances of the three color lights for the color shift improvement layer in the bending area are determined.

Through step S105, determining the color shift improvement layer 50 is actually determining the transmittances of the three color lights for the color shift improvement layer in the bending area.

Afterwards, at step S107, the color shift improvement layer 50 can be formed based on the obtained transmittances to manufacture a display panel having a color shift improvement function.

In some embodiments, through step S1051, it can be known that, in the bending area S2, the initial light emission ratio of the first color light in the frontal viewing direction is greater than the initial light emission ratio of the second color light in the frontal viewing direction; the initial light emission ratio of the second color light in the frontal viewing direction is greater than the initial light emission ratio of the third color light in the frontal viewing direction; the color shift improvement layer 50 can change the light emission ratio of at least one color light among the first color light, the second color light, and the third color light in the bending area S2 of the display panel 2, which includes:
reducing the light emission ratio of the first color light in the frontal viewing direction or simultaneously reducing the light emission ratios of the first color light and the second color light in the frontal viewing direction.

That is, the first color light is the color light that requires adjustment of transmittance or the first color light and the second color light are the color lights that require adjustment of transmittance.

When forming the color shift improvement layer to improve the color shift phenomenon, in some embodiments, the method includes:
the color shift improvement layer is provided with a first color resistance material for reducing the first color light transmittance and a second color resist material for reducing the second color light transmittance;
where, in the bending area, the first color light transmittance in the frontal viewing direction of the color shift improvement layer is the first color shift transmittance, the transmittance of the second color light in the frontal viewing direction of the color shift improvement layer is the second color shift transmittance, and the first color shift transmittance is less than or equal to the second color shift transmittance.

Continuing to refer to FIG. 6, it can be seen that, as the bending degree of the display panel increases, that is, the frontal viewing angle increases, the brightness attenuation ratio (i.e., the transmittance attenuation ratio) of the blue light decreases the fastest, followed by the green light, and the red light decreases the slowest. That is, the light emission ratio of the red light in the frontal viewing direction is greater than the light emission ratio of the green light in the frontal viewing direction, the light emission ratio of the green light in the frontal viewing direction is greater than the light emission ratio of the blue light in the frontal viewing direction. In other words, the red light transmittance in the frontal viewing direction is greater than the green light transmittance in the frontal viewing direction, the green light transmittance in the frontal viewing direction is greater than the blue light transmittance in the frontal viewing direction. As shown in FIG. 8 to FIG. 10, the color shift improvement layer 50 can simultaneously reduce the light emission ratios of the red light and green light in the frontal viewing direction to reduce the difference values between the light emission ratios of the three color lights, so as to improve the color shift phenomenon. That is, the first color resistance material 51 which reduces the light emission ratio of red light is provided, and the second color resist material 52 which reduces the light emission ratio of the green light is provided.

Certainly, in some other embodiments, the color shift improvement layer can reduce the light emission ratio of the first color light in the frontal viewing direction to reduce the difference values between the light emission ratios of the three color lights, so as to improve the color shift phenomenon.

Correspondingly, in some embodiments, when forming the color shift improvement layer to improve the color shift phenomenon, the method includes:
Providing a first color resist material for reducing the first color light transmittance in the color shift improvement layer to reduce the light emission ratio of the first color light in the frontal viewing direction.

For example, the color shift improvement layer is provided with the first color resist material for reducing the red light transmittance to reduce the light emission ratio of the red light in the frontal viewing direction.

In some embodiments, the color shift improvement layer 50 is completely transparent to the third color light.

In some embodiments, for a relatively large bending angle, after determining the bending area, the method further includes:
based on the bending angle of the bending area S2 of the display panel 2, dividing the bending area S2 into one or more bending subareas; where the different bending subareas have a different transmittance for at least one color light; the bending angle of each bending subarea is a preset angle, where the preset angle is greater than or equal to 5° and less than or equal to 15°.

Correspondingly, the color shift improvement layers corresponding to respective bending subareas are set respectively based on the frontal viewing angle of the specific bending subarea. For example, as shown in FIG. 2, the color shift improvement layer corresponding to the first bending subarea S21 and the color shift improvement layer corresponding to the second bending subarea S22 are set separately, and the transmittances of respective color lights are set respectively for the corresponding frontal viewing angles, so as to improve color shift by subarea with a better improvement effects.

In some embodiments, the display panel 2 includes an encapsulation layer 40 provided on a side of the light emitting layer 30 facing away from the substrate 10; at step S107, based on the color shift improvement layer 50 manufacturing the display panel 2 includes:
providing the color shift improvement layer 50 on a side of the encapsulation layer 40 facing away from light emitting layer 30, or providing the color shift improvement layer 50 between the encapsulation layer 40 and the light emitting layer 30.

In the present disclosure, the structural embodiments and the method embodiments may complement each other without conflict.

In the present disclosure, terms “first” and “second” are used for descriptive purposes only and are not to be construed as indicating or implying a relative importance. The term “a plurality” indicates two or more, unless specifically defined otherwise.

After considering the specification and practicing the present disclosure, the skilled in the art may easily conceive of other implementations of the present disclosure. The present application is intended to cover any variations, uses, or adaptations of the present disclosure, which follow the general principle of the present disclosure and include common knowledge or conventional technical means in the art that are not disclosed in the present disclosure. The specification and examples are to be regarded as illustrative only. The true scope and spirit of the present disclosure are pointed out by the following claims.

It is to be understood that the present disclosure is not limited to the precise structures described above and shown in the accompanying drawings and may be modified or changed without departing from the scope of the present disclosure. The scope of the present disclosure is limited only by the appended claims.

1. A display panel, comprising a non-bending area and at least one bending area on at least one side of the non-bending area, wherein, the display panel comprises:
a substrate;
a light-emitting layer, provided on the substrate, where the light emitting layer comprises a plurality of light-emitting units, each of the plurality of light-emitting units comprises a plurality of light-emitting subunits, the plurality of light-emitting subunits are configured to emit a first color light, a second color light, and a third color light; and
a color shift improvement layer, provided on a side of the light emitting layer facing away from the substrate, and on the at least one bending areas;
wherein difference values between light emission ratios of the first color light, the second color light, and the third color light in a frontal viewing direction range from 0-8%, wherein the frontal viewing direction is perpendicular to at least a part of a surface of the non-bending area.

2. The display panel according to claim 1, wherein the difference values between the light emission ratios of the first color light, the second color light, and the third color light in the frontal viewing direction range from 0-5%.

3. The display panel according to claim 1, wherein, in the bending area, an initial light emission ratio of the first color light in the frontal viewing direction is greater than an initial light emission ratio of the second color light in the frontal viewing direction, the initial light emission ratio of the second color light in the frontal viewing direction is greater than an initial light emission ratio of the third color light in the frontal viewing direction; and
the color shift improvement layer is provided with a first color resist material for reducing a first color light transmittance.

4. The display panel according to claim 1, wherein, in the bending area, an initial light emission ratio of the first color light in the frontal viewing direction is greater than an initial light emission ratio of the second color light in the frontal viewing direction, and the initial light emission ratio of the second color light in the frontal viewing direction is greater than an initial light emission ratio of the third color light in the frontal viewing direction; and
the color shift improvement layer is provided with a first color resistance material for reducing a transmittance for the first color light, and a second color resist material for reducing a transmittance for the second color light.

5. The display panel according to claim 4, wherein, in the bending area, the transmittance for the first color light in the frontal viewing direction of the color shift improvement layer is a first color shift transmittance, the transmittance for the second color light in the frontal viewing direction of the color shift improvement layer is a second color shift transmittance, and the first color shift transmittance is less than or equal to the second color shift transmittance.

6. The display panel according to claim 1, wherein, the color shift improvement layer is completely transparent to the third color light; and/or,
among the first color light, the second color light, and the third color light, one is red light, one is green light, and one is blue light.

7. The display panel according to claim 1, wherein, the bending area comprises one or more bending subareas, a number of the bending subareas is divided based on a range of a frontal viewing angle of the bending area of the display panel; wherein, different bending subareas have a different transmittance for at least one color light, a bending angle of each bending subarea is a preset angle, the preset angle is greater than or equal to 5° and less than or equal to 15°.

8. The display panel according to claim 1, wherein, the display panel comprises an encapsulation layer provided on the side of the light emitting layer facing away from the substrate; wherein, the color shift improvement layer is provided on a side of the encapsulation layer facing away from the light-emitting layer, or the color shift improvement layer is provided between the encapsulation layer and the light-emitting layer.

9. A method of manufacturing a display panel, for manufacturing the display panel according to claim 1, wherein the method comprises:
determining corresponding relationships between light emission ratios respectively for the first color light, the second color light, and the third color light at frontal viewing angles of the display panel and the frontal viewing angles;
determining a range of the frontal viewing angles of a bending area of the display panel to determine the bending area of the display panel;
determining a color shift improvement layer, based on the range of the frontal viewing angles of the display panel, and the corresponding relationships between the light emission ratios respectively for the first color light, the second color light, and the third color light at frontal viewing angles of the display panel and the frontal viewing angle s; and
manufacturing the display panel based on the color shift improvement layer;
wherein difference values between the light emission ratios of the first color light, the second color light, and the third color light in a frontal viewing direction range from 0-8%.

10. The method according to claim 9, wherein, in the bending area, an initial light emission ratio of the first color light in the frontal viewing direction is greater than an initial light emission ratio of the second color light in the frontal viewing direction, the initial light emission ratio of the second color light in the frontal viewing direction is greater than an initial light emission ratio of the third color light in the frontal viewing direction; manufacturing the display panel based on the color shift improvement layer comprises:
providing a first color resist material in the color shift improvement layer for reducing a transmittance for the first color light, to reduce the light emission ratio of the first color light in the frontal viewing direction.

11. The method according to claim 9, wherein, in the bending area, an initial light emission ratio of the first color light in the frontal viewing direction is greater than an initial light emission ratio of the second color light in the frontal viewing direction, and the initial light emission ratio of the second color light in the frontal viewing direction is greater than an initial light emission ratio of the third color light in the frontal viewing direction;
manufacturing the display panel based on the color shift improvement layer comprises:
providing a first color resistance material in the color shift improvement layer for reducing a transmittance for the first color light and providing a second color resist material in the color shift improvement layer for reducing a transmittance for the second color light;
wherein, in the bending area, the transmittance for the first color light in the frontal viewing direction of the color shift improvement layer is a first color shift transmittance, the transmittance for the second color light in the frontal viewing direction of the color shift improvement layer is a second color shift transmittance, and the first color shift transmittance is less than or equal to the second color shift transmittance.

12. The method according to claim 9, wherein the method further comprises:
based on bending angles of the bending area of the display panel, dividing the bending area into one or more bending subareas, wherein different bending subareas have a different transmittance for at least one color light; a bending angle of each bending subarea is a preset angle, wherein the preset angle is greater than or equal to 5° and less than or equal to 15°.

13. A display device, wherein the display device comprises a display panel comprising a non-bending area and at least one bending area on at least one side of the non-bending area, wherein, the display panel comprises:
a substrate;
a light-emitting layer, provided on the substrate, where the light emitting layer comprises a plurality of light-emitting units, each of the plurality of light-emitting units comprises a plurality of light-emitting subunits, the plurality of light-emitting subunits are configured to emit a first color light, a second color light, and a third color light; and
a color shift improvement layer, provided on a side of the light emitting layer facing away from the substrate, and on the at least one bending areas;
wherein difference values between light emission ratios of the first color light, the second color light, and the third color light in a frontal viewing direction range from 0-8%, wherein the frontal viewing direction is perpendicular to at least a part of a surface of the non-bending area.

14. The display device according to claim 13, wherein the difference values between the light emission ratios of the first color light, the second color light, and the third color light in the frontal viewing direction range from 0-5%.

15. The display device according to claim 13, wherein, in the bending area, an initial light emission ratio of the first color light in the frontal viewing direction is greater than an initial light emission ratio of the second color light in the frontal viewing direction, the initial light emission ratio of the second color light in the frontal viewing direction is greater than an initial light emission ratio of the third color light in the frontal viewing direction; and
the color shift improvement layer is provided with a first color resist material for reducing a first color light transmittance.

16. The display device according to claim 13, wherein, in the bending area, an initial light emission ratio of the first color light in the frontal viewing direction is greater than an initial light emission ratio of the second color light in the frontal viewing direction, and the initial light emission ratio of the second color light in the frontal viewing direction is greater than an initial light emission ratio of the third color light in the frontal viewing direction; and
the color shift improvement layer is provided with a first color resistance material for reducing a transmittance for the first color light, and a second color resist material for reducing a transmittance for the second color light.

17. The display device according to claim 16, wherein, in the bending area, the transmittance for the first color light in the frontal viewing direction of the color shift improvement layer is a first color shift transmittance, the transmittance for the second color light in the frontal viewing direction of the color shift improvement layer is a second color shift transmittance, and the first color shift transmittance is less than or equal to the second color shift transmittance.

18. The display device according to claim 13, wherein, the color shift improvement layer is completely transparent to the third color light; and/or,
among the first color light, the second color light, and the third color light, one is red light, one is green light, and one is blue light.

19. The display device according to claim 13, wherein, the bending area comprises one or more bending subareas, a number of the bending subareas is divided based on a range of a frontal viewing angle of the bending area of the display panel; wherein, different bending subareas have a different transmittance for at least one color light, a bending angle of each bending subarea is a preset angle, the preset angle is greater than or equal to 5° and less than or equal to 15°.

20. The display device according to claim 13, wherein, the display panel comprises an encapsulation layer provided on the side of the light emitting layer facing away from the substrate; wherein, the color shift improvement layer is provided on a side of the encapsulation layer facing away from the light-emitting layer, or the color shift improvement layer is provided between the encapsulation layer and the light-emitting layer.
